(19) United States
(12) Patent Application Publication
(10) Pub. No.: US 2026/0338974 A1
(43) Pub. Date: Oct. 29, 2026

(54) ULTRAFAST AND HIGH-EFFICIENCY ELECTRON DETECTOR BASED ON NANOPOLYCRYSTALLINE BORON NITRIDE

(71) Applicant: Sun Yat-sen University, Guangzhou (CN)

(72) Inventors: Wei ZHENG, Shenzhen City (CN); Siqi ZHU, Shenzhen City (CN)

(21) Appl. No.: 19/704,468

(22) Filed: Jun. 11, 2026

Related U.S. Application Data
(63) Continuation of application No. PCT/CN2025/131101, filed on Oct. 30, 2025.

(30) Foreign Application Priority Data
Jan. 24, 2025 (CN) 2025101135979

(51) Int. Cl. G01T 1/202; G01T 1/20

(52) U.S. Cl. CPC G01T 1/2023; G01T 1/2002; G01T 1/2018

(57) ABSTRACT

The present disclosure relates to the technical field of electron detectors, and discloses an ultrafast and high-efficiency electron detector based on nano-polycrystalline boron nitride (NPBN). The electron detector includes an NPBN scintillator, a light guide, and a photomultiplier tube, wherein the NPBN scintillator and the photomultiplier tube are connected to a front end and a rear end of the light guide, respectively. The NPBN material of the NPBN scintillator is prepared by using a single-crystal sapphire wafer as a substrate, using NH₃ and BCl₃, or NH₃ and BF₃, as source gases, and performing growth in a chemical vapor deposition furnace. In the present disclosure, the NPBN scintillator has a short scintillation decay time and a high scintillation light yield, and can achieve ultrafast and high-efficiency electron radiation detection when applied in an electron detector.

### CROSS-REFERENCE TO RELATED APPLICATIONS

This application is a continuation of International Application No. PCT/CN 2025/131101, filed on Oct. 30, 2025, which claims priority to Chinese Patent Application No. 202510113597.9, filed on Jan. 24, 2025. All of the aforementioned applications are incorporated herein by reference in their entireties.

### TECHNICAL FIELD

The present disclosure relates to the technical field of electron detectors, and in particular, to an ultrafast and high-efficiency electron detector based on nano-polycrystalline boron nitride (NPBN).

### BACKGROUND

Semiconductor wafer inspection technology is a critical procedure for ensuring the quality and performance of semiconductor devices, including not only physical defect detection on wafer surfaces but also precise measurements of critical dimensions. Electron beam inspection technology plays an irreplaceable role in this field due to its high precision and high resolution. For example, an electron beam inspection (EBI) apparatus can detect, in real time, defect conditions of semiconductor wafers, particularly electrical defects in internal circuits. A critical dimension scanning electron microscope (CD-SEM) monitors critical process parameters by performing critical dimension measurements on electron beam microscopic images.

In these electron beam inspection systems, an electron detector converts secondary electron or backscattered electron signals into visible light signals for detection. An electron scintillator is a key component for achieving high-efficiency electron detection. The electron scintillator is required to possess the following characteristics: a high light yield to ensure sufficient signal intensity, a short decay time to achieve fast signal response, a low afterglow to avoid image trailing, and excellent radiation resistance to maintain long-term stability. At present, commonly used electron scintillation materials are yttrium aluminum garnet doped with cerium (YAG:Ce, Ce-doped Y₃Al₅O₁₂) single crystals and yttrium aluminum perovskite doped with cerium (YAP:Ce, Ce-doped YAlO₃) single crystals. These materials are widely adopted due to their relatively simple preparation processes and low costs. However, most YAG:Ce scintillators used to date suffer from excessively long decay times and high afterglow, which limit their performance in certain fast and high-precision applications. The YAP:Ce scintillator has a fast decay capability of approximately 30 nanoseconds (ns), thereby improving electron detection efficiency. Nevertheless, it remains of great significance to continuously explore and develop new electron scintillators to further promote the advancement and application expansion of electron beam inspection technology.

### SUMMARY

In view of the above-described background, the present disclosure provides an ultrafast and high-efficiency electron detector based on NPBN and a method of preparing NPBN. Compared with a conventional YAP:Ce scintillator, the electron detector and the preparation method of the present disclosure achieve a shorter decay time and higher luminous efficiency.

To achieve the above objectives, the present disclosure adopts the following technical solutions.

In a first aspect, the present disclosure provides an ultrafast and high-efficiency electron detector based on NPBN. The electron detector includes an NPBN scintillator, a light guide, and a photomultiplier tube, wherein the NPBN scintillator and the photomultiplier tube are connected to a front end and a rear end of the light guide, respectively;
the NPBN scintillator is configured to receive electron irradiation and, upon electron excitation, utilize a carrier confinement effect of a nano-polycrystalline (NP) structure thereof to generate nanosecond-scale ultrafast and high-brightness scintillation;
the NPBN material of the NPBN scintillator is prepared by using a single-crystal sapphire wafer as a substrate, using NH₃ and BCl₃, or NH₃ and BF₃, as source gases, and performing growth in a vertical chemical vapor deposition furnace;
the light guide is configured to transmit scintillation light to the photomultiplier tube; and
the photomultiplier tube is configured to receive the scintillation light transmitted by the light guide and record photon information.

Further, a surface of the NPBN scintillator is deposited with a layer of aluminum having a thickness of 50 nm to 60 nm by magnetron sputtering.

Further, the electron detector further includes a Faraday cup disposed at a front end of the NPBN scintillator for secondary electron detection in an electron beam inspection system.

Further, a central portion of the NPBN scintillator is provided with a circular hole to form an annular structure for backscattered electron detection in an electron beam inspection system.

Further, the light guide is any one of a quartz optical fiber, a glass optical fiber, and a plastic optical fiber.

Further, the NPBN scintillator is obtained by a preparation method including the steps of:

S1: selecting a single-crystal sapphire having a large lattice mismatch with boron nitride as a substrate, and selecting an aluminum-polar surface that facilitates nucleation as a growth surface;

S2: securing the substrate using a graphite fixture, placing the graphite fixture together with the substrate into a vertical chemical vapor deposition furnace, evacuating, and then raising a temperature to a reaction temperature by lateral heating;

S3: introducing NH₃ and BCl₃, or NH₃ and BF₃, as source gases, with N₂ as a carrier gas, into the vertical chemical vapor deposition furnace;

S4: after introducing the source gases, maintaining constant gas flow rates and temperature; and finally, cutting off a power supply, cooling, allowing the boron nitride and the sapphire substrate to cool to room temperature in the vertical chemical vapor deposition furnace, followed by removing the boron nitride and the sapphire substrate from the vertical chemical vapor deposition furnace, wherein the boron nitride automatically detaches, obtaining an NPBN material; and

S5: cutting the NPBN material into a predetermined size suitable for the electron detector, thereby obtaining the NPBN scintillator.

Still further, step S5 of the preparation method of the NPBN scintillator further includes depositing an aluminum layer having a thickness of 50 nm to 60 nm on a surface of the NPBN material by magnetron sputtering, and then cutting the NPBN material into the predetermined size.

Still further, in step S2 of the preparation method of the NPBN scintillator, after evacuating, lateral heating is performed to raise a temperature to a reaction temperature of 1300 °C to 1600 °C.

Still further, in step S3 of the preparation method of the NPBN scintillator, a gas volume ratio of the source gases NH₃ to BCl₃, or NH₃ to BF₃, is controlled to be from 1.2:1 to 1.5:1.

Still further, in step S4 of the preparation method of the NPBN scintillator, after introducing the source gases, the temperature is maintained at 1300 °C to 1600 °C for 240 min to 360 min.

Compared with the prior art, the present disclosure provides the following beneficial effects.

1. Compared with a YAP:Ce single crystal, the NPBN film of the present disclosure has a shorter luminescence decay time and a faster response speed. This fast response characteristic enables the reduction of image blurring during electron beam imaging, thereby further improving image quality.

2. Compared with a YAP:Ce single crystal, the NPBN film of the present disclosure exhibits higher luminous efficiency, with a maximum photoluminescence quantum yield (PLQY) of up to 39.8%. This indicates that the NPBN film of the present disclosure has excellent luminescent properties.

3. In the present disclosure, the boron nitride scintillator grown using a vertical chemical vapor deposition method is applied to an electron detector. Since the NPBN scintillator has a short scintillation decay time and a high scintillation light yield, the electron detector based on NPBN constructed in the present disclosure can achieve ultrafast and high-efficiency electron detection. The electron detector of the present disclosure can be used for secondary electron detection and backscattered electron detection in an electron beam inspection system, thereby providing a new option for electron beam inspection technology.

### BRIEF DESCRIPTION OF THE DRAWINGS

FIG. 1 is a schematic structural diagram of an electron detector adopting an NPBN electron scintillator according to Example 1 of the present disclosure.

FIG. 2 is a schematic structural diagram and imaging diagram of an electron detector based on NPBN for secondary electron detection according to Example 2 of the present disclosure.

FIG. 3 is a schematic structural diagram and imaging diagram of an electron detector based on NPBN for backscattered electron detection according to Example 3 of the present disclosure.

FIG. 4 is a photograph, a growth schematic diagram, and an installation schematic diagram of NPBN according to Example 4 of the present disclosure.

FIG. 5 is a result diagram showing a cross-sectional structure of NPBN captured using a transmission electron microscope (TEM) according to Example 5 of the present disclosure.

FIG. 6 is a result diagram showing a comparative analysis of an NPBN scintillator and a commercial YAP:Ce scintillator under the same excitation conditions according to Example 6 of the present disclosure.

### REFERENCE NUMERALS IN THE DRAWINGS

1—NPBN scintillator; 2—light guide; 3—photomultiplier tube; 4—Faraday cup; 5—circular hole.

### DETAILED DESCRIPTION OF THE EMBODIMENTS

The technical solutions in the embodiments of the present disclosure will be clearly and completely described below with reference to the drawings in the embodiments of the present disclosure. Obviously, the described embodiments are only a part of the embodiments of the present disclosure, rather than all of the embodiments. Based on the embodiments of the present disclosure, all other embodiments obtained by those of ordinary skill in the art without creative efforts fall within the scope of protection of the present disclosure.

### Example 1: Ultrafast and High-Efficiency Electron Detector Based on NPBN

Example 1 provides the ultrafast and high-efficiency electron detector based on NPBN according to the present disclosure. As shown in FIG. 1, an ultrafast and high-efficiency electron detector based on NPBN is provided. The electron detector includes an NPBN scintillator 1, a light guide 2, and a photomultiplier tube 3, wherein the NPBN scintillator 1 and the photomultiplier tube 3 are connected to a front end and a rear end of the light guide 2, respectively.

The NPBN scintillator 1 is prepared by a rapid film growth process using a high-temperature chemical vapor deposition method. The NPBN scintillator 1 is configured to receive electron irradiation and, upon electron excitation, utilize a carrier confinement effect of a NP structure thereof to generate nanosecond-scale ultrafast and high-brightness scintillation.

The light guide 2 is configured to transmit scintillation light to the photomultiplier tube 3. Specifically, the light guide 2 is one of a quartz optical fiber, a glass optical fiber, and a plastic optical fiber.

The photomultiplier tube 3 is configured to receive the scintillation light transmitted by the light guide 2 and to record photon information.

In operation, after the NPBN scintillator 1 receives electron irradiation and generates scintillation light, the light guide 2 transmits the scintillation light to the photomultiplier tube 3. After receiving the scintillation light signal, the photomultiplier tube 3 records photon information for subsequent readout.

To prevent charge accumulation on the surface of the NPBN scintillator 1 caused by electron bombardment, this example further employs a magnetron sputtering technique to deposit a layer of aluminum having a thickness of 50 nm to 60 nm on the surface of the NPBN scintillator 1. This aluminum layer not only effectively prevents charge accumulation but also serves as a reflective layer that reflects backward-propagating scintillation light, thereby enhancing the light output capability of the scintillator. Furthermore, in this example, the NPBN scintillator 1 may also be cut into a predetermined size suitable for the electron detector.

Because the NPBN scintillator 1 has a short decay time and a high light yield, in combination with the light guide 2 and the photomultiplier tube 3 which are designed to be compatible with the scintillator, the electron detector of the present disclosure achieves faster time resolution and higher detection efficiency.

### Example 2: Electron Detector Based on NPBN for Secondary Electron Detection

Based on Example 1, Example 2 provides a modified electron detector suitable for secondary electron detection in an electron beam inspection system.

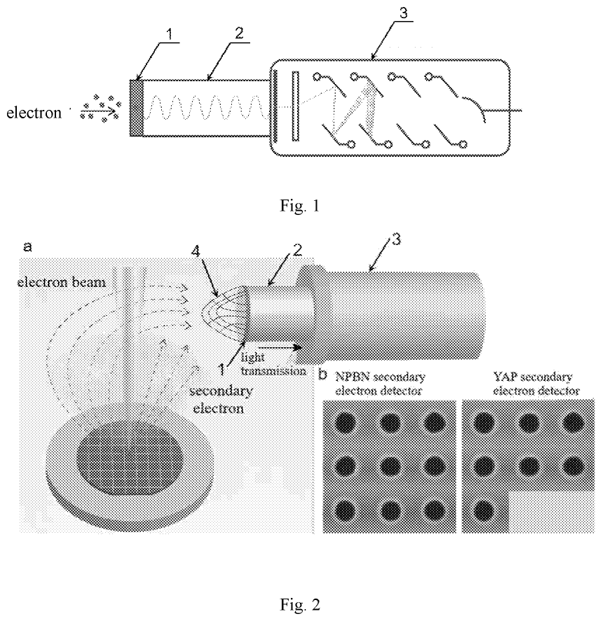

FIGS. 2a and 2b are a schematic structural diagram and an imaging diagram, respectively, of the electron detector based on NPBN for secondary electron detection according to this example. As shown in FIG. 2 a, based on Example 1, the electron detector for secondary electron detection of this example further includes a Faraday cup disposed at a front end of the NPBN scintillator 1. Because secondary electrons have low energy, the secondary electrons are susceptible to deflection under the influence of an electric field. During the operation of the secondary electron detector, a voltage-biased Faraday cup attracts and accelerates scattered secondary electrons from various directions. Once these accelerated electrons strike the NPBN scintillator 1, the accelerated electrons cause the scintillator to emit light. The generated scintillation light is then transmitted through the light guide 2 and finally collected and recorded by the photomultiplier tube 3. Because the NPBN of the present disclosure has faster and more efficient electron scintillation performance, the secondary electron detector based on NPBN, compared with conventional secondary electron detectors, significantly shortens the time required for scanning electron signals to acquire images, thereby achieving faster and more efficient sample detection (see FIG. 2b).

### Example 3: Electron Detector Based on NPBN for Backscattered Electron Detection

Based on Example 1, Example 3 provides a modified electron detector suitable for backscattered electron detection in an electron beam inspection system.

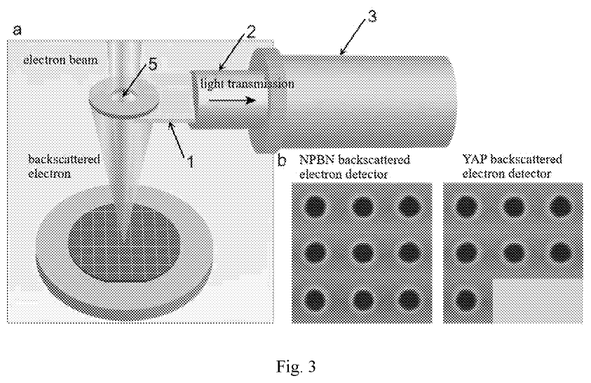

FIGS. 3a and 3b are a schematic structural diagram and an imaging diagram, respectively, of the electron detector based on NPBN for backscattered electron detection according to this example. As shown in FIG. 3a, based on Example 1, in the electron detector for backscattered electron detection of this example, a central portion of the NPBN scintillator 1 is provided with a circular hole 5 to form an annular structure. The purpose of this geometrical arrangement is to allow an incident electron beam to directly reach a sample surface, thereby exciting backscattered electrons. Although the incident electron beam simultaneously excites both secondary electrons and backscattered electrons, the secondary electrons, having low energy, do not generate significant scintillation light after reaching the backscattered electron detector. In contrast, the high-energy backscattered electrons effectively excite the scintillator to emit light. The light emitted by the scintillator is transmitted through the light guide 2 and similarly collected and recorded by the photomultiplier tube 3. Because the NPBN has faster and more efficient electron scintillation performance, the backscattered electron detector based on NPBN of this example, compared with conventional backscattered electron detectors, significantly shortens the time required for scanning electron signals to acquire images, thereby achieving faster and more efficient sample detection (see FIG. 3b).

### Example 4: Method of Preparing NPBN Scintillator for Electron Detector

Example 4 provides a method of preparing the NPBN scintillator for the electron detector according to any one of Examples 1 to 3. In this example, the NPBN is prepared by using a 6-inch single-crystal sapphire wafer as a substrate, using NH₃ and BCl₃ (or NH₃ and BF₃) as source gases, and performing growth in a vertical chemical vapor deposition furnace. The method of preparing the NPBN material includes the following steps S1 to S6.

S1: selecting a 6-inch single-crystal sapphire having a large lattice mismatch with boron nitride as a substrate, and selecting an aluminum-polar surface that facilitates nucleation as a growth surface.

In this example, because the aluminum-polar surface of sapphire has a high surface energy, which is favorable for adsorption and nucleation, the aluminum surface of the substrate is selected for the growth of the NPBN.

S2: securing the substrate using a graphite fixture, placing the graphite fixture together with the substrate into a vertical chemical vapor deposition furnace, evacuating, and then raising a temperature to a reaction temperature of 1500 °C by lateral heating.

S3: introducing NH₃ and BCl₃ (or NH₃ and BF₃), as source gases, with N₂ as a carrier gas, into the vertical chemical vapor deposition furnace, such that the gas mixture reacts rapidly on the substrate to generate boron nitride and promote continuous boron nitride growth. S4: maintaining constant gas flow rates; controlling a gas volume ratio of the source gases NH₃ and BCl₃ (or NH₃ and BF₃), to be 1.2:1 to promote boron nitride formation; after introducing the source gases, maintaining the temperature at 1500 °C for 300 min, during which period boron nitride grains nucleate on the sapphire substrate and gradually grow to form a NP structure; and finally, cutting off a power supply, cooling, allowing the boron nitride and the sapphire substrate to cool to room temperature in the vertical chemical vapor deposition furnace, followed by removing the boron nitride and the sapphire substrate from the vertical chemical vapor deposition furnace, wherein the boron nitride automatically detaches, obtaining an NPBN material of the present disclosure.

S5: depositing an aluminum layer having a thickness of 50 nm to 60 nm on a surface of the NPBN material by magnetron sputtering; and cutting the NPBN material into a predetermined size suitable for the electron detector, thereby obtaining the NPBN scintillator of the present disclosure.

In this example, the aluminum layer not only effectively prevents charge accumulation but also serves as a reflective layer that reflects backward-propagating scintillation light, thereby enhancing the light output capability of the scintillator.

S6: mounting the cut NPBN scintillator at a front end of the light guide, thereby obtaining the electron detector based on NPBN of the present disclosure.

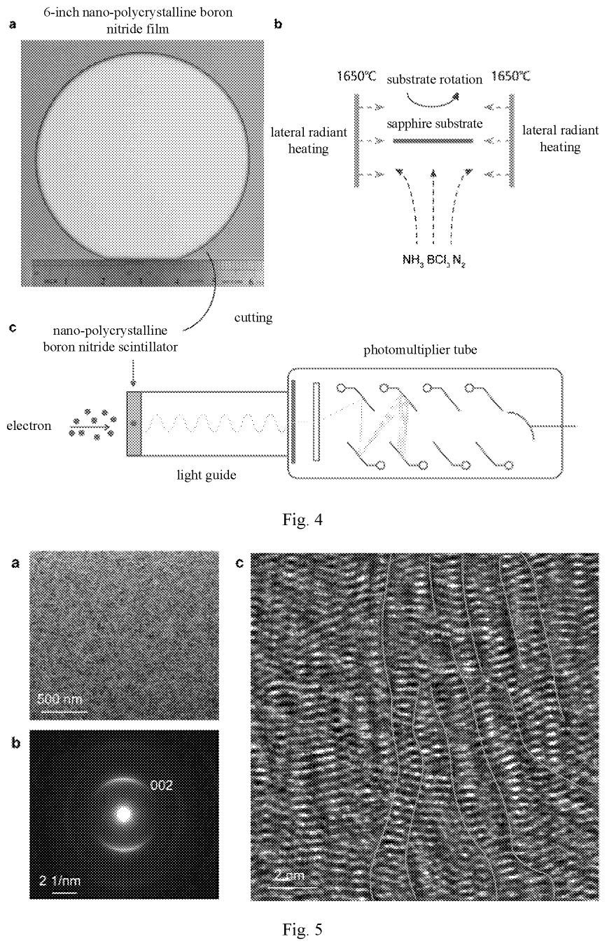

A growth schematic diagram, a photograph, and an installation schematic diagram of the NPBN prepared using this example are shown in FIG. 4, wherein FIG. 4a is a photograph of the NPBN, FIG. 4b is a growth schematic diagram of the NPBN, and FIG. 4c is an installation schematic diagram of the NPBN scintillator.

### Example 5: Cross-Sectional Structural Analysis of NPBN by Transmission Electron Microscopy

Sapphire and boron nitride have a large lattice mismatch, and the boron nitride film reaches a thickness on the order of micrometers, which typically causes the grown boron nitride film to automatically detach from the sapphire substrate. A cross-sectional structure of the grown boron nitride material is imaged using a transmission electron microscope (TEM), and the results are shown in FIG. 5, wherein FIG. 5a is a low-magnification TEM image, FIG. 5b is a selected area electron diffraction (SAED) pattern, and FIG. 5c is a high-resolution TEM (HRTEM) image.

Under ideal conditions, boron nitride should exhibit a layered structure. However, as shown in the low-magnification TEM image of FIG. 5a, the structure of the grown boron nitride film appears relatively disordered. In FIG. 5b, the SAED pattern reveals that the grown boron nitride film grows predominantly along the c-axis direction, with a major crystal plane of (002), exhibiting polycrystalline characteristics. Further in-depth analysis of the HRTEM image shows that the atomic arrangement of the grown boron nitride film is non-uniform, with distorted lattice structures forming nanocluster-like structures (see FIG. 5c). On a nanoscale localized region, the boron nitride maintains an ordered layered structure, but overall exhibits polycrystalline properties, which is defined as a NP structure. The formation of this structure can be attributed, on one hand, to the large lattice mismatch between the boron nitride layer and the sapphire substrate, leading to island growth; and on the other hand, to the use of a relatively large reactant gas flow rate during the growth process, which accelerates the growth rate, resulting in non-uniform lattice arrangement and inducing localized distortion. Therefore, in this example, NPBN is successfully grown by a chemical vapor deposition method.

### Example 6: Comparative Analysis of NPBN Scintillator and Commercial YAP:Ce Scintillator

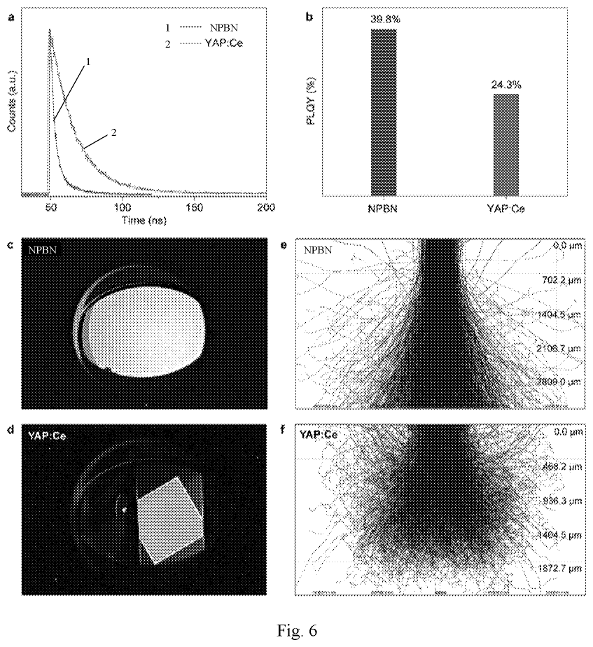

A comparative analysis of electron beam imaging is performed under identical excitation conditions on an NPBN film scintillator and a commercial YAP:Ce single-crystal scintillator. The results are shown in FIG. 6, wherein FIG. 6a shows the luminescence time response of NPBN and YAP:Ce under identical excitation conditions; FIG. 6b is a graph showing a comparison of PLQY; FIG. 6c and FIG. 6 d are grayscale photographs showing scintillation of NPBN and YAP:Ce under 2 MeV electron beam excitation, respectively; and FIG. 6e and FIG. 6f show simulations of electron penetration depth distribution for NPBN and YAP:Ce under 2 MeV electron beam excitation, respectively.

As shown in the figures, the luminescence decay time of NPBN (9.4 ns) is significantly shorter than that of YAP:Ce (40.6 ns), indicating a faster time response. This fast response characteristic enables the reduction of image blurring during electron beam imaging, thereby further improving image quality (see FIG. 6a). Furthermore, the peak luminescence wavelength of NPBN is approximately 385 nm, which is similar to that of YAP:Ce, and thus does not require the use of photomultiplier tubes that have enhanced sensitivity in the longer wavelength region. Further PLQY test results also confirm that NPBN exhibits higher luminescence efficiency compared to YAP:Ce, with a maximum PLQY of up to 39.8% (see FIG. 6 b). This strong luminescence originates from the carrier confinement effect induced by the NP structure of boron nitride. Excited carriers are confined by the structure, which makes the carriers more likely to undergo radiative recombination, thereby enhancing the luminescence capability. These results demonstrate the excellent luminescent properties of NPBN.

To further directly observe the scintillation light yield of NPBN, luminescence photographs of NPBN and YAP:Ce scintillators under electron beam excitation were taken in this example. When the electron beam (with an energy of 2 MeV) vertically impinges on the scintillator, the generated light is first deflected at a 90° angle by a mirror and then captured by a camera. Luminescence images of the scintillators were taken while maintaining the same electron beam pulse frequency and camera integration time. FIG. 6c and FIG. 6d show grayscale photographs of scintillation of a 100 μm thick NPBN and a 500 μm thick YAP:Ce, respectively. As shown in the figures, under identical excitation conditions, the 100 μm thick NPBN exhibits higher contrast, i.e., a higher scintillation light yield, compared to the 500 μm thick commercial YAP:Ce.

Further, this example also used Casino software to simulate the penetration depth of the electron beam into NPBN and YAP:Ce scintillators under the aforementioned identical excitation conditions. The simulation results show that, under these conditions, the electron beam can easily penetrate the 100 μm thick NPBN as well as the 500 μm thick YAP:Ce (see FIG. 6e and FIG. 6f). The fact that NPBN maintains a high scintillation light yield even at a relatively small thickness further confirms the great potential of NPBN as an electron scintillator.

The above are only preferred embodiments of the present disclosure and are not intended to limit the present disclosure. Any modifications, equivalent substitutions, improvements, etc. made within the spirit and principles of the present disclosure shall be included in the protection scope of the present disclosure.

What is claimed is:

1. An ultrafast and high-efficiency electron detector based on nano-polycrystalline boron nitride (NPBN), comprising an NPBN scintillator (1), a light guide (2), and a photomultiplier tube (3), wherein the NPBN scintillator (1) and the photomultiplier tube (3) are connected to a front end and a rear end of the light guide (2), respectively;
wherein the NPBN scintillator (1) is configured to receive electron irradiation and, upon electron excitation, utilize a carrier confinement effect of a nano-polycrystalline (NP) structure thereof to generate nanosecond-scale ultrafast and high-brightness scintillation;
the NPBN material of the NPBN scintillator (1) is prepared by using a single-crystal sapphire wafer as a substrate, using NH₃ and BCl₃, or NH₃ and BF₃, as source gases, and performing growth in a vertical chemical vapor deposition furnace;
the light guide (2) is configured to transmit scintillation light to the photomultiplier tube (3); and
the photomultiplier tube (3) is configured to receive the scintillation light transmitted by the light guide (2) and record photon information; and
the NPBN scintillator (1) is obtained by a preparation method comprising the steps of:
S1: selecting a single-crystal sapphire having a large lattice mismatch with boron nitride as a substrate, and selecting an aluminum-polar surface that facilitates nucleation as a growth surface;
S2: securing the substrate using a graphite fixture, placing the graphite fixture together with the substrate into a vertical chemical vapor deposition furnace, evacuating, and then raising a temperature to a reaction temperature by lateral heating;
S3: introducing NH₃ and BCl₃, or NH₃ and BF₃, as source gases, with N₂ as a carrier gas, into the vertical chemical vapor deposition furnace;
S4: after introducing the source gases, maintaining constant gas flow rates and temperature; and finally, cutting off a power supply, cooling, allowing the boron nitride and the sapphire substrate to cool to room temperature in the vertical chemical vapor deposition furnace, followed by removing the boron nitride and the sapphire substrate from the vertical chemical vapor deposition furnace, wherein the boron nitride automatically detaches, obtaining an NPBN material; and
S5: cutting the NPBN material into a predetermined size suitable for the electron detector, thereby obtaining the NPBN scintillator.

2. The electron detector according to claim 1, wherein a surface of the NPBN scintillator (1) is deposited with a layer of aluminum having a thickness of 50 nm to 60 nm by magnetron sputtering.

3. The electron detector according to claim 1, wherein the electron detector further comprises a Faraday cup (4) disposed at a front end of the NPBN scintillator (1) for secondary electron detection in an electron beam inspection system.

4. The electron detector according to claim 1, wherein a central portion of the NPBN scintillator (1) is provided with a circular hole (5) to form an annular structure for backscattered electron detection in an electron beam inspection system.

5. The electron detector according to claim 1, wherein the light guide (2) is any one of a quartz optical fiber, a glass optical fiber, and a plastic optical fiber.

6. The electron detector according to claim 1, wherein step S5 of the preparation method of the NPBN scintillator (1) further comprises depositing an aluminum layer having a thickness of 50 nm to 60 nm on a surface of the NPBN material by magnetron sputtering, and then cutting the NPBN material into the predetermined size.

7. The electron detector according to claim 1, wherein in step S2 of the preparation method of the NPBN scintillator (1), after evacuating, lateral heating is performed to raise a temperature to a reaction temperature of 1300 °C to 1600 °C.

8. The electron detector according to claim 1, wherein in step S3 of the preparation method of the NPBN scintillator (1), a gas volume ratio of the source gases NH₃ to BCl₃, or NH₃ to BF₃, is controlled to be from 1.2:1 to 1.5:1.

9. The electron detector according to claim 1, wherein in step S4 of the preparation method of the NPBN scintillator (1), after introducing the source gases, the temperature is maintained at 1300 °C to 1600 °C for 240 min to 360 min.
